(19) United States
(12) Patent Application Publication
(10) Pub. No.: US 2026/0338829 A1
(43) Pub. Date: Oct. 29, 2026

(54) TEST BOARD FOR IMPROVING SIGNAL CHARACTERISTICS

(71) Applicant: ATECO INC., Gunpo-si (KR)

(72) Inventors: Taek Seon LEE, Hwaseong-si (KR); Ho Nam KIM, Seongnam-si (KR); Sung Chul MOON, Gunpo-si (KR)

(21) Appl. No.: 19/642,383

(22) Filed: Apr. 8, 2026

(30) Foreign Application Priority Data
Apr. 23, 2025 (KR) 10-2025-0053257
Mar. 10, 2026 (KR) 10-2026-0043210

(51) Int. Cl. G01R 1/04; G01R 1/20

(52) U.S. Cl. CPC G01R 1/0466; G01R 1/045; G01R 1/20

(57) ABSTRACT

A test board according to an embodiment of the present disclosure comprises: a device pocket configured to receive the test target device with the device terminal facing downwards, wherein the device pocket has a pocket terminal electrically connected to the device terminal in a state in which the test target device is received therein; a test tray on which the device pocket may be placed, wherein the test tray may be configured to electrically connect the pocket terminal to the test apparatus while being in contact with the test apparatus; and a signal quality improving unit installed in at least one of the test tray and the device pocket and configured to adjust a signal to be transmitted to the test target device through the pocket terminal.

### CROSS REFERENCE TO RELATED APPLICATIONS

Priority to Korean patent application number 10-2025-0053257 filed on Apr. 23, 2025, and Korean patent application number 10-2026-0043210 filed on Mar. 10, 2026, the entire disclosure of which is incorporated by reference herein, is claimed.

### TECHNICAL FIELD

The present disclosure relates to a test board for improving signal characteristics. This work was supported by the Technology development Program (RS-2024-00487757) funded by the Ministry of SMEs and Startups (MSS, Korea).

### BACKGROUND

As technology advances, the demand for new memory modules capable of processing data more efficiently while providing higher bandwidth is steadily increasing. As part of a response to such demand, HBM (High Bandwidth Memory) has adopted an innovative design that forms a memory chip stack. HBM uses vertically stacked memory chips to achieve high bandwidth and may offer the advantages of occupying less space while reducing power consumption. These characteristics have served as the background for HBM gaining attention as the importance of memory bandwidth and power efficiency continues to grow in high-performance computing and graphics processing systems.

Like the HBM described above, recently developed memory modules have data processing speeds on the order of several GHz. As a result, test equipment for performing mounting tests on memory modules before supplying them to the market is also required to have fast signal transmission speeds. In this regard, one representative method for improving signal transmission speed is a method of shortening the length of the signal path.

Meanwhile, probe cards generally used in conventional mounting tests have a diameter of approximately 500 mm. Considering such a diameter of the probe card, the signal path of a general probe card may be formed to an average length of approximately 250 to 400 mm.

### SUMMARY

A purpose to be achieved by the present disclosure is to provide a mounting test technology capable of shortening the substantial signal path length compared to the prior art.

Another purpose to be achieved by the present disclosure is to provide a mounting test technology having improved signal characteristics compared to the prior art. In this case, the signal characteristics may be related to, for example, response speed and/or noise reduction.

The purposes of the present disclosure are not limited to the aforementioned purposes, and other purposes not mentioned will be clearly understood by those skilled in the art from the description below.

A test board for improving signal characteristics according to an embodiment of the present disclosure for solving the above purposes is configured to be transported with a test target device having device terminals loaded thereon and to electrically connect the test target device to a test apparatus that tests the test target device while being in contact with the test apparatus.

The test board according to an embodiment of the present disclosure comprises: a device pocket configured to load the test target device with the device terminal facing downwards, wherein the device pocket has a pocket terminal electrically connected to the device terminal in a state in which the test target device is loaded therein; a test tray on which the device pocket may be placed, wherein the test tray may be configured to electrically connect the pocket terminal to the test apparatus while being in contact with the test apparatus; and a signal quality improving unit installed in at least one of the test tray and the device pocket and configured to adjust a signal to be transmitted to the test target device through the pocket terminal.

The device pocket may include a plurality of the device pockets arranged on the test tray.

The signal quality improving unit may include a plurality of signal conditioning modules corresponding to the plurality of device pockets, wherein each of plurality of signal conditioning modules may be electrically connected to the pocket terminal of the corresponding device pocket.

The signal conditioning modules may include a capacitor electrically connected to the pocket terminal to remove noise to be transmitted to the test target device.

The signal conditioning modules may further include a ground member electrically connected to the capacitor, a distal end of the ground member being exposed to an outside from a bottom surface of the test tray such that the ground member may be electrically connected to a ground element installed in the test apparatus while the test tray may be in contact with the test apparatus.

The signal conditioning modules may include a power supply electrically connected to the pocket terminals to regulate power to be delivered to the test target device.

The device pockets may comprise: a pocket body having an inner space defined therein, wherein the inner space has an open upper surface; a seating plate disposed so as to define a bottom of the inner space, wherein the seating plate may have a hole defined therein in which an upper end portion of the pocket terminal may be inserted such that the pocket terminal and the device terminal are into contact with each other while the test target device is placed thereon; and an interposer having an upper surface to which a lower end portion of the pocket terminal is fixed, wherein a connection terminal electrically connected to the pocket terminal may be formed at a lower surface of the interposer.

The pocket terminal may include a plurality of pocket terminals, and the device terminal may include a plurality of device terminals corresponding to the plurality of pocket terminals.

The connection terminal may include a plurality of connection terminals respectively electrically connected to the plurality of pocket terminals, wherein the plurality of connection terminals is formed at a lower surface of the interposer.

A spacing between adjacent ones of the connection terminals may be greater than a spacing between adjacent ones of the pocket terminals.

The signal conditioning module may be installed so as to be positioned on one side of the interposer.

The signal conditioning module may be embedded inside the interposer.

The test tray may be formed to have a through-hole extending therethrough so that the device pocket may be inserted therein. In a state in which the device pocket is inserted into the through-hole, the connection terminal may be exposed toward a space under the test tray, such that the test target device may be electrically connected to the test apparatus through the connection terminal in contact with the test apparatus while the test tray is seated on the test apparatus.

The test tray may be formed to have a seating groove recessed therein so that the device pocket may be seated therein. The test tray may include a tray terminal having an upper end in contact with the connection terminal of the device pocket seated in the seating groove, and a lower end exposed to an outside from a bottom surface of the test tray.

The signal conditioning modules may be installed in a space between adjacent ones of the plurality of device pockets and on the test tray.

Other specific details of the present disclosure are included in the detailed description and drawings.

According to the embodiments of the present disclosure, at least the following effects are achieved.

The substantial signal path length may be shortened to approximately 100 mm or less.

The time required for testing may be effectively reduced based on the short signal path.

Unnecessary noise may be removed immediately before a test signal is delivered to the test target device, thereby improving the quality of the test signal.

The effects according to the present disclosure are not limited by the content exemplified above, and more various effects are included in this specification.

### BRIEF DESCRIPTION OF THE DRAWINGS

FIG. 1 is a drawing schematically illustrating a test board according to an embodiment of the present disclosure.

FIG. 2 is a drawing conceptually representing a test target device.

FIG. 3 is a perspective view of a device pocket according to an embodiment of the present disclosure.

FIG. 4 is an exploded perspective view of the device pocket shown in FIG. 3.

FIG. 5 is a drawing for illustrating an electrical path from a pocket terminal to a connection terminal of a device pocket according to an embodiment of the present disclosure.

FIG. 6 is a drawing conceptually representing a state in which a test board according to an embodiment of the present disclosure is seated in a test apparatus.

FIG. 7 is a drawing conceptually representing a state in which a test board having a test tray of a different form from that of FIG. 6 is seated in a test apparatus.

### DETAILED DESCRIPTION

The advantages and features of the present disclosure, and the methods for achieving them, will be clarified with reference to the embodiments described in detail below taken together with the accompanying drawings. However, the present disclosure is not limited to the embodiments disclosed below, but may be implemented in various different forms. The present embodiments are provided merely to make the disclosure of the present disclosure complete and to fully inform those skilled in the art of the scope of the disclosure, and the present disclosure is defined only by the scope of the claims.

In addition, the embodiments described herein will be described with reference to cross-sectional views and/or schematic diagrams that are ideal exemplary views of the present disclosure. Therefore, the forms of the exemplary views may be modified due to manufacturing techniques and/or tolerances. In addition, each of the components shown in each drawing of the present disclosure may be shown somewhat enlarged or reduced for convenience of explanation. The same reference numerals refer to the same components throughout the specification.

Directions such as upper, lower, front, rear, left, or right mentioned hereinafter are merely described with one direction as a reference for convenience of explanation, and the present disclosure is not limited to the described direction. That is, it is obvious that in the actual installation and use process of the present disclosure, the direction may be changed to a different direction from the description below, and the present disclosure should be construed to include such embodiments.,

The “test target device” mentioned below may refer to a semiconductor product packaged at the first level to the second level. As one example, the test target device may refer to an HBM die. However, the test target device to which the present disclosure is applicable is not necessarily limited to a semiconductor product packaged at the first to second level. That is, the modification may be made while maintaining the core features of the present disclosure, and thus may also be applicable to testing of semiconductor products packaged at the third to fourth level.

Hereinafter, the present disclosure will be described with reference to the drawings for illustrating a test board for improving signal characteristics according to an embodiment of the present disclosure.

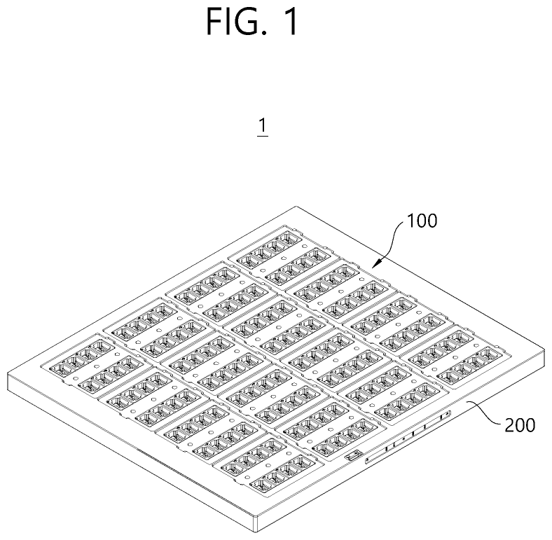

First, FIG. 1 is a drawing schematically illustrating a test board according to an embodiment of the present disclosure.

As shown in FIG. 1, a test board 1 is provided in a form in which a plurality of device pockets 100 are mounted on a test tray 200.

Each device pocket 100 is formed to allow one test target device to be loaded therein. The device pocket 100 has an inner space defined therein and has an open upper surface. The test target device enters the inner space through the open upper surface and may be loaded inside the device pocket 100.

The test tray 200 is a plate-shaped member that mounts the device pockets 100 in a predetermined arrangement. The test tray 200 may be formed with through-holes each extending therethrough so that one device pocket 100 is inserted therein. Alternatively, the test tray 200 may be formed with seating grooves each recessed from the upper surface so that one device pocket 100 is seated therein.

A plurality of device pockets 100 are mounted on the test tray 200 in a predetermined arrangement. The predetermined arrangement here is an arrangement corresponding to the arrangement of sockets of the test apparatus described below. When the test tray 200 is seated on the upper surface of the test apparatus by such an arrangement, each device pocket 100 is positioned above the corresponding socket.

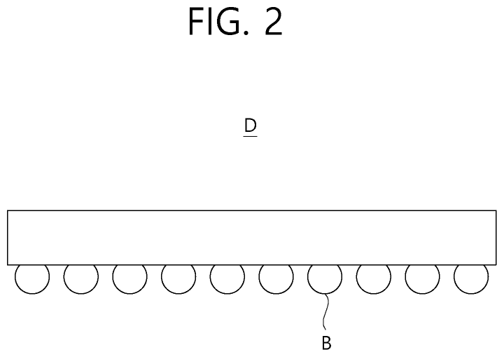

Hereinafter, with reference to FIG. 2, the test target device loaded in the present disclosure is described. FIG. 2 is a drawing conceptually representing a test target device. In this regard, FIG. 2 represents the test target device D as viewed from the side.

As shown in FIG. 2, the test target device D may have device terminals B formed on the lower surface thereof. The device terminals B may be components implementing electrical contact points for electrically connecting a semiconductor product to a main board. As one example, the device terminals B may be provided as solder balls implementing a BGA (Ball Grid Array).

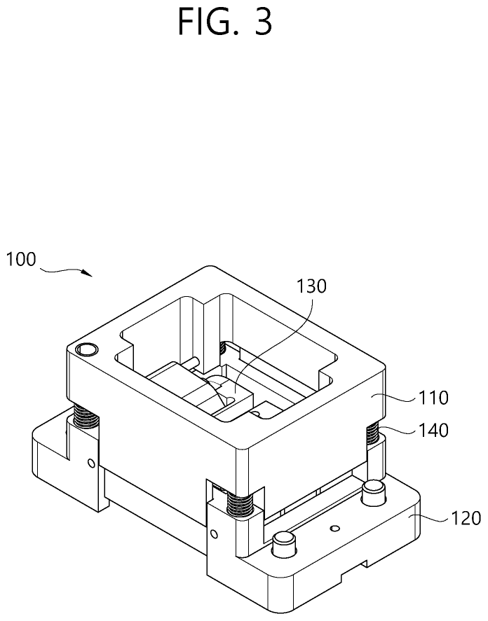

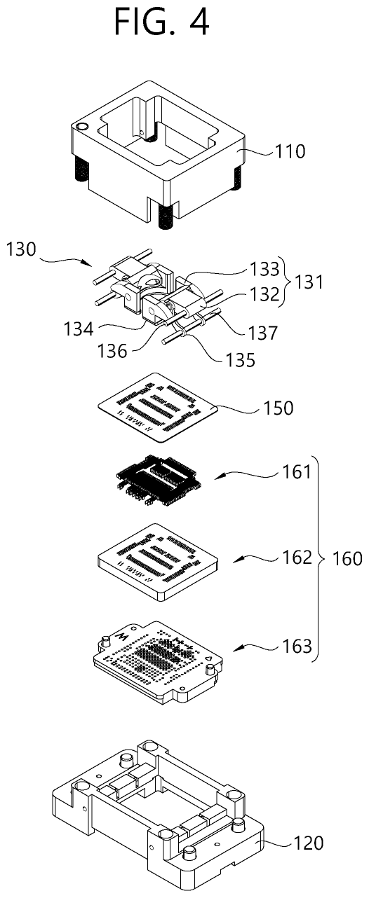

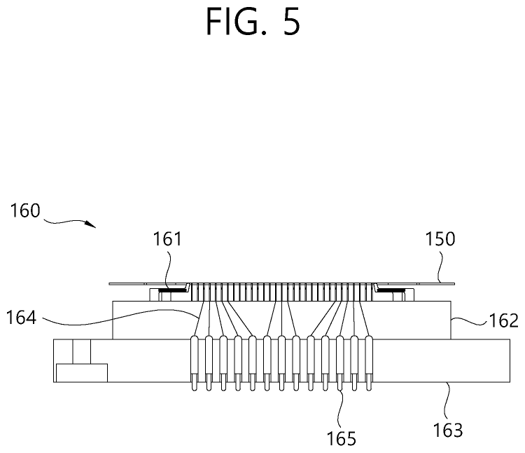

Hereinafter, with reference to FIGS. 3 to 5, a device pocket according to an embodiment of the present disclosure is described. FIG. 3 is a perspective view of a device pocket according to an embodiment of the present disclosure. FIG. 4 is an exploded perspective view of the device pocket shown in FIG. 3. In addition, FIG. 5 is a drawing for illustrating the electrical path from a pocket terminal to a connection terminal of a device pocket according to an embodiment of the present disclosure.

Referring to FIGS. 3 and 5, the device pocket 100 according to an embodiment of the present disclosure may be configured to selectively fix the test target device while one test target device is loaded therein.

Recently developed test target devices have an increasing number of device terminals while the spacing between the device terminals is becoming even more compact. This trend further increases the difficulty of the alignment work for connecting test target devices to the test apparatus. Moreover, the test apparatus simultaneously tests a plurality of test target devices in order to efficiently operate the mounting test. Therefore, in order to conduct a single mounting test in the test apparatus, a plurality of test target devices must be aligned corresponding to the sockets of the test apparatus. Such precise alignment work for a plurality of test target devices not only takes considerable time but also increases the complexity of the overall system.

Taking this situation into account, the device pocket 100 according to the present disclosure may be configured to reduce the difficulty of the alignment work between the test board and the test apparatus. Specifically, when a mounting test is performed using the test board according to the present disclosure, once the test target device is loaded into the device pocket 100, the alignment work is performed on a test apparatus and test board unit basis inside the mounting test system. In this regard, the device pocket 100 fixes the position of the precisely loaded test target device while being transported inside the mounting test system.

In order to reduce the difficulty of the alignment work, the device pocket 100 has contact and connection means arranged at a wider spacing than the spacing between the device terminals. When the test board is transported inside the mounting test system and seated in the test apparatus, the contact and connection means of the device pocket 100 are electrically connected to the contact points of the sockets of the test apparatus. That is, the electrical connection between the test board and the test apparatus is implemented by aligning the contact and connection means with the contact points of the sockets and then seating the test board in the test apparatus. In this regard, since the spacing between the contact and connection means is wider than the spacing between the device terminals, the work of aligning the device pocket 100 with the socket has a lower degree of difficulty than the work of directly aligning the test target device with the socket. In this regard, the contact and connection means aligned with the contact points of the socket is the connection terminal 165, described below.

Hereinafter, the configuration of the device pocket 100 for performing the above functions is described. Referring to FIGS. 3 to 5, the device pocket 100 may include a pocket body 110, a fixed body 120, a latch link 130, an elastic member 140, a seating plate 150, and an interposer 160. The respective components are configured to be coupled to each other in the vertical direction.

The pocket body 110 is implemented in a shape in which the center portion is penetrated in the vertical direction. The penetrated portion of the pocket body 110 becomes the inner space in which the test target device is loaded when the device pocket 100 is assembled. The test target device is transferred to the inner space through the open upper surface of the pocket body 110. Meanwhile, the pocket body 110 may be coupled to the fixed body 120 so as to be capable of reciprocating a predetermined height in the vertical direction.

The fixed body 120 may be an approximately plate-shaped member that is inserted into or seated in the test tray and fixed therein. The fixed body 120, similar to the pocket body 110, may be penetrated in the vertical direction at the center portion. In this regard, the fixed body 120 and the pocket body 110 may be penetrated so as to have the same central axis as each other. In the center portion of the fixed body 120 thus penetrated, the latch link 130, the seating plate 150, and the interposer 160 may be installed.

Elastic members 140 may be mounted at each corner of the upper surface of the fixed body 120. A plurality of elastic members 140 are disposed between the fixed body 120 and the pocket body 110 to elastically support the pocket body 110 with respect to the fixed body 120. As one example, the elastic member 140 may be provided as a coil spring or a conventionally known spring equivalent thereto.

The latch link 130 may be configured such that the pivot angle thereof is adjustable according to the gap between the pocket body 110 and the fixed body 120. The latch link 130 is configured symmetrically left and right, and each end thereof may be configured to press the upper portion of the test target device loaded in the inner space.

The latch link 130 may include a latch portion 131 and a link 135. The latch portion 131 may be configured to include a connection portion 132 and a pressing portion 133. The connection portion 132 is located on one end side of the latch link 130 and may be rotatably coupled to the pocket body 110 by inserting a first connection pin 136 thereinto. The pressing portion 133 is located on the other end side of the latch link 130 and is configured to press the upper portion of the test target device. The pressing portion 133 may have a thermal pad 134 so as to minimize the influence of heat when pressing the upper end of the test target device. The link 135 extends downward from the connection portion 132 and has a second connection pin 137 extending parallel to the first connection pin 136. The link 135 may be rotatably coupled to the fixed body 120 by inserting the second connection pin 137 thereinto.

Meanwhile, the operation of the latch link 130 may be geometrically predetermined. In the present disclosure, the configuration is such that when the pocket body 110 descends to the position closest to the fixed body 120, the pressing portion 133 may rotate 90 degrees or more upward. Conversely, when the external force is removed, the pocket body 110 rises from the fixed body 120 by the elastic member 140 and returns to the initial height. As a result, the latch link 130 conversely has its angle adjusted in the direction of 90 degrees while pressing the upper surface of the test target device.

Meanwhile, the pressing portions 133 provided in a pair of latch links 130 may be formed to be concave at the portions facing each other in the closed position. The concave structure of the pressing portion 133 is formed so that, in a state in which a PNP device has precisely positioned the test target device in the inner space, the latch link 130 may be closed with the PNP device remaining in the inner space. To this end, the concave structure of the pressing portion 133 is formed in a shape that does not contact the PNP device while the angle of the latch portion 131 is being adjusted.

The seating plate 150 forms the bottom of the inner space when the device pocket 100 is assembled. The seating plate 150 is disposed at the upper end of the fixed body 120 and may have holes into which the upper end portions of the pocket terminals 161, described below, are received. The seating plate 150 may be installed so as to be capable of slight elevation relative to the fixed body 120. Referring more specifically to FIG. 5, the seating plate 150 is disposed at a certain interval spaced upward from the intermediate block 162, described below.

The seating plate 150 may be pressed downward by the latch link 130 when the latch link 130 is switched to the closed state while the test target device is seated thereon. Alternatively, the seating plate 150 may be pressed downward by the weight of the seated test target device. Therefore, the seating plate 150 may descend a predetermined height by the pressing force of the latch link 130 and/or the weight of the test target device. As the seating plate 150 descends, the pocket terminals 161 rise relatively with respect to the seating plate 150. This change in height induces the upper end portions of the pocket terminals 161 to come into contact with the device terminals of the test target device seated on the seating plate 150.

The interposer 160 is configured to expand the electrical contact position with respect to the test target device. The interposer 160 may include pocket terminals 161, an intermediate block 162, and a fixed block 163.

The pocket terminal 161 may be a conventionally used pin-shaped member for electrical contact. For example, the pocket terminal 161 may be provided as a type of conventionally known pogo pin or MEMS pin. Alternatively, the pocket terminal 161 may be provided as a conductive member equivalent thereto.

The intermediate block 162 is a block whose upper surface has the lower end portions of the pocket terminals 161 fixed thereto and which has conductive paths 164 inside. The conductive paths 164 are implemented by conductive members extending in a direction that expands the spacing of the pocket terminals 161. For example, the conductive paths 164 may be printed electrical circuits.

The fixed block 163 is positioned under the intermediate block 162 and has connection terminals 165 each electrically connected to the conductive paths 164 exposed at the lower surface thereof. Since the connection terminals 165 may be configured similarly to the pocket terminals 161, a redundant description thereof is omitted. The connection terminals 165 are inserted while extending through the fixed block 163, and the upper end and the lower end may protrude from the upper surface or the lower surface of the fixed block 163, respectively. The upper end portions of the connection terminals 165 are inserted into the intermediate block 162 and connected to the conductive paths 164. In addition, the lower end portions of the connection terminals 165 may come into contact with the contact points of the socket while the test board is seated in the test apparatus. Alternatively, the lower end portions of the connection terminals 165 may come into contact with tray terminals, described below. A detailed description of this will be provided below.

In the description above, an example in which the interposer 160 is configured in block form has been described; however, it may also be implemented in a thinner structure in order to shorten the signal path. As one example, the interposer 160 may be configured in a thin structure such as a multilayer circuit or a glass substrate. The reduction in the thickness of the interposer 160 means a shortening of the length of the physical signal path between the test target device and the test apparatus. The shortening of the signal path length means a reduction in the substantial response time during the mounting test, and this effect may be maximized as the operating frequency increases.

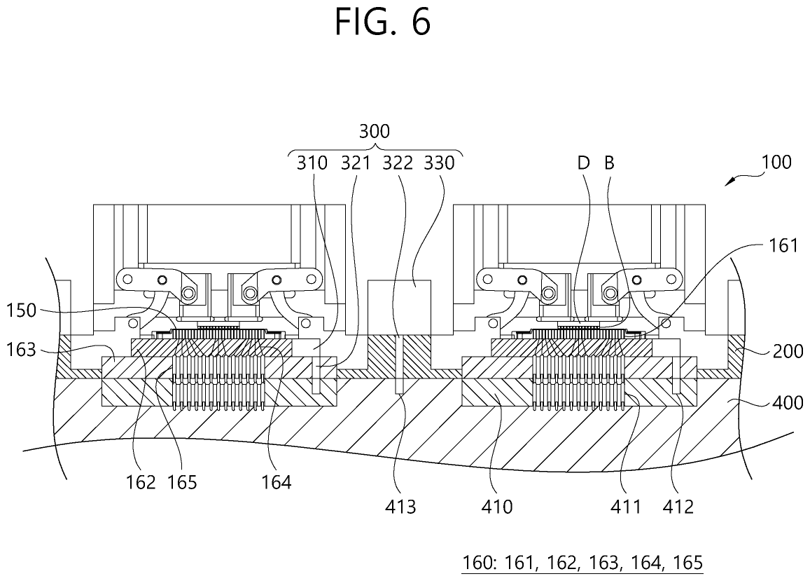

Hereinafter, with reference to FIG. 6, the signal quality improving unit according to an embodiment of the present disclosure and the connected state between the test board and the test apparatus according to an embodiment of the present disclosure are described. FIG. 6 is a drawing conceptually representing a state in which a test board according to an embodiment of the present disclosure is seated in a test apparatus.

As shown in FIG. 6, the test target device D is loaded in the device pocket 100 with the device terminals B facing downwards. In this state, the device terminals B come into contact with the pocket terminals 161 protruding from the seating plate 150. As a result, in the state of FIG. 6, the device terminals B are electrically connected to the test apparatus 400 through the pocket terminals 161, the conductive paths 164, and the connection terminals 165. In this regard, the test tray 200 shown in FIG. 6 is an embodiment having a through-hole into which the device pocket 100 is inserted. Referring to FIG. 6, in a state in which the device pocket 100 is inserted into the test tray 200, the connection terminals 165 are exposed in the space below the test tray 200.

The test apparatus 400 has sockets 410 positioned under each device pocket 100 while the test tray 200 is seated on the upper surface thereof. The socket 410 has socket terminals 411 electrically connected to the connection terminals 165 exposed at the lower surface of the test tray 200. In this regard, the socket terminals 411 serving as the contact points of the socket 410 may be configured identically or similarly to the pocket terminals 161, or may be implemented in another conventionally known manner. As one example, the socket terminals 411 may be configured as pogo pins. Or, as another example, the socket terminals 411 may be provided as conductive members implementing a conductive path in a socket 410 implemented as a conductive rubber pad.

The signal quality improving unit is configured to adjust the signal delivered to the test target device D. For example, the signal quality improving unit may be configured to remove noise in the signal to be transmitted from the test apparatus 400 to the test target device D while shortening the substantial signal path to the test target device D. In order to perform the above functions, the signal quality improving unit may be installed in at least one of the test tray 200 and the device pocket 100.

More specifically, the signal quality improving unit may include a plurality of signal conditioning modules 300 respectively installed corresponding to the device pockets 100. Although not shown, the signal conditioning module 300 may be electrically connected to the pocket terminals 161, the conductive paths 164, and the connection terminals 165 through conventionally known methods. In this regard, the signal conditioning module 300 installed corresponding to one device pocket 100 may include an internal module 310 and an external module 330, which are distinguished from each other according to their installation positions. In addition, the signal conditioning module 300 may include an internal module connecting member 321 for connecting the internal module 310 to the test apparatus 400, and an external module connecting member 322 for connecting the external module 330 to the test apparatus 400.

Correspondingly, the test apparatus 400 may include, in a state in which the test tray 200 is seated therein, an internal module contact element 412 in contact with the internal module connecting member 321, and an external module contact element 413 in contact with the external module connecting member 322.

In this regard, the internal module 310 and the external module 330, the internal module connecting member 321 and the external module connecting member 322, and the internal module contact element 412 and the external module contact element 413 have been named differently according to their installation positions or corresponding components, but their configurations may be identical or similar to each other.

The internal module 310 may be built into the interior of the device pocket 100 so as to be positioned on one side of the interposer 160. More specifically, the internal module 310 may be inserted into the device pocket 100 so as to be positioned on one lateral side of the intermediate block 162. Alternatively, the internal module 310 may be inserted into the intermediate block 162 or the fixed block 163 constituting the interposer 160 and embedded inside the interposer 160. The fixed block 163 may have an internal module connecting member 321 connected to the internal module 310 built therein. The internal module connecting member 321 is positioned so as to come into contact with the internal module contact element 412 formed in the socket 410 in a state in which the test tray 200 is seated in the test apparatus 400.

The external module 330 may be installed in the space between adjacent ones of the device pockets 100 and on the test tray 200. In addition, the test tray 200 may have an external module connecting member 322 extending in the vertical direction so as to be connected to the external module 330 built therein. The external module connecting member 322 is positioned so as to come into contact with the external module contact element 413 exposed on the upper surface of the test apparatus 400 in a state in which the test tray 200 is seated in the test apparatus 400.

The internal module 310 and the external module 330 may be provided as a capacitor or a power supply.

When the internal module 310 or the external module 330 is a capacitor, the signal conditioning module 300 may serve the role of bypassing high-frequency noise in the test signal delivered from the test apparatus 400 to the test target device D to ground. To aid understanding, since a capacitor has a lower impedance at higher frequencies, the high-frequency noise included in the signal traveling to the test target device D through the socket terminals 411 is diverted to the capacitor, which has a relatively lower impedance, and thus removed.

When the internal module 310 or the external module 330 is a capacitor, the internal module connecting member 321 and the external module connecting member 322 may be ground members for grounding the capacitor. The ground member may be formed based on a conductive material. For example, the ground member may be a metal-based shaft or may be provided in the form of a cable conventionally used. In addition, at this time, the internal module contact element 412 and the external module contact element 413 may be ground elements that ground components installed in the test apparatus 400. Similarly, the ground elements may be selected from conventionally known configurations. As one example, the ground element may be a metal member or a cable connected to ground.

When the internal module 310 or the external module 330 is a power supply, the signal conditioning module 300 may receive power through the test apparatus 400 and, based thereon, deliver a stable power signal to the test target device D. For the supply of a stable power signal, the power supply may include a conventionally known filter configured to remove ripple and/or noise. When the internal module 310 or the external module 330 is a power supply, since the test target device D operates based on a stable power signal, the overall signal quality may be improved.

When the internal module 310 or the external module 330 is a power supply, the internal module connecting member 321 and the external module connecting member 322 may be power receiving members for receiving power supply. The power receiving member may be formed based on a conductive material. Since this configuration may be identical or similar to the ground member, a detailed description thereof is omitted. In addition, at this time, the internal module contact element 412 and the external module contact element 413 may be power supply elements configured to be electrically connected to a power line that distributes power to the test apparatus 400. Similarly, the power supply elements may be selected from conventionally known configurations. For example, since the power supply elements may be configured identically or similarly to the ground elements, a detailed description thereof is omitted.

In FIG. 6, the signal conditioning module 300 corresponding to one device pocket 100 is shown as including both the internal module 310 and the external module 330, but this is merely for the purpose of illustration of all components for convenience of explanation, and it is also possible for either the internal module 310 or the external module 330 to be omitted.

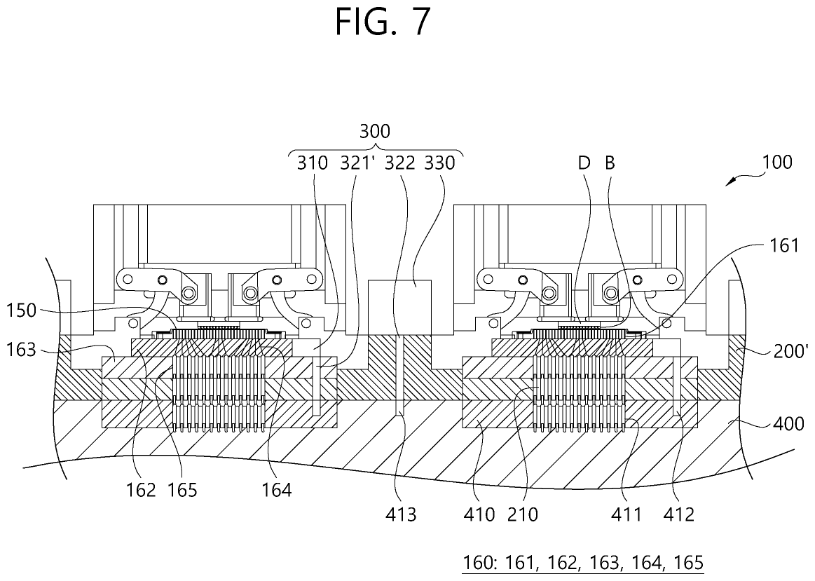

Hereinafter, with reference to FIG. 7, the case of using a test tray 200′ of a different embodiment from FIG. 6 is described. FIG. 7 is a drawing conceptually representing a state in which a test board having a test tray of a different form from FIG. 6 is seated in a test apparatus. For convenience of explanation, the same reference numerals are used for parts that are identical or similar to the embodiment of FIG. 6, and descriptions of common parts are omitted.

The test tray 200′ shown in FIG. 7, unlike FIG. 6, is an embodiment in which a seating groove is formed rather than a through-hole extending through the test tray 200′. The seating groove may be formed by being partially recessed downward from the upper surface of the test tray 200′ corresponding to the shape of the lower end of the device pocket 100. Due to this structure, in the embodiment of FIG. 7, the bottom surface of the device pocket 100 is not exposed below the test tray 200′.

Instead, a plurality of tray terminals 210 are installed at the bottom of the test tray 200′ of FIG. 7. For example, the tray terminals 210 may be installed by being inserted into terminal insertion holes formed extending through the test tray 200′ below the seating groove. In this regard, the plurality of tray terminals 210 have an arrangement corresponding to the plurality of connection terminals 165 and the plurality of socket terminals 411.

The upper end portions of the tray terminals 210 may be exposed at the bottom of the seating groove, and the lower end portions of the tray terminals 210 may be exposed to the outside from the bottom surface of the test tray 200′. Therefore, when the device pocket 100 is seated in the seating groove, the connection terminals 165 may be seated on the upper ends of the tray terminals 210. Similarly, when the test tray 200′ is seated in the test apparatus 400, the tray terminals 210 may be seated on the upper ends of the socket terminals 411. Therefore, according to the embodiment of FIG. 7, the test target device D is electrically connected to the socket terminals 411 through the pocket terminals 161, the conductive paths 164, the connection terminals 165, and the tray terminals 210.

The tray terminals 210 of the test tray 200′ may be provided to prevent the connection terminals 165 from directly contacting the socket terminals 411. When the tray terminals 210 are provided, the stress applied to the connection terminals 165 during the repeated testing process may be reduced, thereby having the effect of extending the service life of the interposer 160.

The internal module connecting member 321′ according to the embodiment of FIG. 7 may protrude by a predetermined length downwards from the fixed block 163, unlike the above-described embodiment. The protruding portion of the internal module connecting member 321′ may be inserted into a member insertion hole extending therethrough downwards from the bottom of the seating groove. While being inserted into the member insertion hole, the internal module connecting member 321′ may be exposed to the external space through the bottom surface of the test tray 200′. Due to this structure, as a result, similar to the above-described embodiment, when the test tray 200′ is seated in the test apparatus 400, the internal module connecting member 321′ comes into contact with the internal module contact element 412.

Alternatively, as another implementation example, the internal module connecting member 321′ according to the present embodiment may, unlike the above-described embodiment, be divided into a component inserted into the fixed block 163 and a component inserted into the member insertion hole. In this case, when the device pocket 100 is seated in the seating groove, the conductive component inserted into the fixed block 163 and the conductive component inserted into the member insertion hole are brought into close contact with each other to form a single internal module connecting member 321′.

Those skilled in the art to which the present disclosure pertains will understand that the present disclosure may be implemented in other specific forms without changing its technical spirit or essential features. Therefore, the embodiments described above should be understood as illustrative in all respects and not restrictive. The scope of the present disclosure is indicated by the following claims rather than the detailed description above, and all changes or modifications derived from the meaning and scope of the claims and the concept of equivalents thereof should be construed as being included within the scope of the present disclosure.

What is claimed is:

1. A test board for improving signal characteristics, the test board being configured to be transported with a test target device having a device terminal loaded thereon and to electrically connect the test target device to a test apparatus for testing the test target device while being in contact with the test apparatus, the test board comprising:
a device pocket configured to load the test target device with the device terminal facing downwards, wherein the device pocket has a pocket terminal electrically connected to the device terminal in a state in which the test target device is loaded therein;
a test tray on which the device pocket is placed, wherein the test tray is configured to electrically connect the pocket terminal to the test apparatus while being in contact with the test apparatus; and
a signal quality improving unit installed in at least one of the test tray and the device pocket and configured to adjust a signal to be transmitted to the test target device through the pocket terminal.

2. The test board for improving signal characteristics of claim 1, wherein the device pocket includes a plurality of the device pockets arranged on the test tray,
wherein the signal quality improving unit includes a plurality of signal conditioning modules, wherein each of the plurality of signal conditioning modules is electrically connected to the pocket terminal of a corresponding device pocket.

3. The test board for improving signal characteristics of claim 2, wherein the signal conditioning modules include a capacitor electrically connected to the pocket terminal to remove noise to be transmitted to the test target device.

4. The test board for improving signal characteristics of claim 3, wherein the signal conditioning modules further include a ground member electrically connected to the capacitor, a distal end of the ground member being exposed to an outside from a bottom surface of the test tray such that the ground member is electrically connected to a ground element installed in the test apparatus while the test tray is in contact with the test apparatus.

5. The test board for improving signal characteristics of claim 2, wherein the signal conditioning modules include a power supply electrically connected to the pocket terminals to regulate power to be delivered to the test target device.

6. The test board for improving signal characteristics of claim 2, wherein the device pockets comprise:
a pocket body having an inner space defined therein, wherein the inner space has an open upper surface;
a seating plate disposed so as to define a bottom of the inner space, wherein the seating plate has a hole defined therein in which an upper end portion of the pocket terminal is inserted such that the pocket terminal and the device terminal are into contact with each other while the test target device is placed thereon; and
an interposer having an upper surface to which a lower end portion of the pocket terminal is fixed, wherein a connection terminal electrically connected to the pocket terminal is formed at a lower surface of the interposer.

7. The test board for improving signal characteristics of claim 6, wherein the device terminal includes a plurality of device terminals, and the pocket terminal includes a plurality of pocket terminals corresponding to the plurality of device terminals and fixed an upper surface of the interposer,
wherein the connection terminal includes a plurality of connection terminals respectively electrically connected to the plurality of pocket terminals, wherein the plurality of connection terminals is formed at a lower surface of the interposer,
wherein a spacing between adjacent ones of the connection terminals is greater than a spacing between adjacent ones of the pocket terminals.

8. The test board for improving signal characteristics of claim 6, wherein the signal conditioning module is installed so as to be positioned on one side of the interposer.

9. The test board for improving signal characteristics of claim 6, wherein the signal conditioning module is embedded inside the interposer.

10. The test board for improving signal characteristics of claim 6, wherein the test tray is formed to have a through-hole extending therethrough so that the device pocket is inserted therein,
wherein in a state in which the device pocket is inserted into the through-hole, the connection terminal is exposed toward a space under the test tray, such that the test target device is electrically connected to the test apparatus through the connection terminal in contact with the test apparatus while the test tray is seated on the test apparatus.

11. The test board for improving signal characteristics of claim 6, wherein the test tray is formed to have a seating groove recessed therein so that the device pocket is seated therein,
wherein the test tray includes a tray terminal having an upper end in contact with the connection terminal of the device pocket seated in the seating groove, and a lower end exposed to an outside from a bottom surface of the test tray.

12. The test board for improving signal characteristics of claim 2, wherein the signal conditioning modules is installed in a space between adjacent ones of the plurality of device pockets and on the test tray.
